(19) United States
(12) Patent Application Publication
(10) Pub. No.: US 2019/0207164 A1
(43) Pub. Date: Jul. 4, 2019

(54) MIRROR DISPLAY DEVICE AND MANUFACTURING METHOD THEREOF

(71) Applicant: Shenzhen China Star Optoelectronics Semiconductor Display Technology Co., LTD., Shenzhen (CN)

(72) Inventors: Chun-hsiung FANG, Shenzhen (CN); Po-yen LU, Shenzhen (CN)

(21) Appl. No.: 15/940,094

(22) Filed: Mar. 29, 2018

Related U.S. Application Data
(63) Continuation of application No. PCT/CN2018/074061, filed on Jan. 24, 2018.

(30) Foreign Application Priority Data
Dec. 28, 2017 (CN) 201711464901.6

(51) Int. Cl. H01L 51/52; H01L 27/32; H01L 51/56; A47G 1/02

(52) U.S. Cl. CPC H01L 51/5271; H01L 27/322; H01L 27/3246; H01L 2227/323; H01L 51/56; A47G 1/02; H01L 51/5284

(57) ABSTRACT

A mirror display device is provided and comprising: a substrate; a cover disposed opposite to the substrate; a plurality of sub-pixels disposed between the substrate and the cover and arranged in array, the sub-pixels comprising organic light emitting elements; a reflection layer disposed between the plurality of sub-pixels and the cover, and the reflection layer including a plurality of apertures corresponding to sub-pixels in one-to-one correspondence. The light transmissivity of each of the sub-pixels could be increased by removing parts of the reflection layer corresponding to the sub-pixels.

### RELATED APPLICATIONS

The present application is a Continuation Application of International Application Number PCT/CN2018/074061, filed Jan. 24, 2018, and claims the priority of China Application No. 201711464901.6, filed Dec. 28, 2017.

### FIELD OF THE DISCLOSURE

The disclosure relates to a display technical field, and more particularly to a mirror display device and a manufacturing method thereof.

### BACKGROUND

Mirror display functions as both mirror and display, it could provide greater flexibility in some application, such as beauty salon, dressing room and so on. In order to function as mirror on the display viewing surface, conventional mirror display could form a semi-transparent metal layer on the encapsulation cover of the organic light emitting diode display (OLED display). When turning off the mirror display, it could use the semi-transparent metal layer as mirror. In addition, it could be functioned as mirror with simple display image.

In the structure of conventional mirror display, since the semi-transparent metal layer formed on the encapsulation cover completely covers the active area of the mirror display, the light transmissivity and the reflectivity of the semi-transparent metal layer has inversely proportional to each other, if the reflectivity is increased, it will sacrifice the light transmissivity, and the display quality is reduced, too. The thickness of normal semi-transparent metal layer is about 10 to 30 nm, the light transmissivity is less than 60%, so that will seriously sacrifice the external light emitting efficiency of the mirror display. Besides, scattering light reflected by the semi-transparent metal layer will also interfere with the light emitted from adjacent sub-pixels to result in color crosstalk.

### SUMMARY

A technical problem to be solved by the disclosure is to provide a mirror display device with increased light transmissivity of sub-pixels and a manufacturing method thereof.

An objective of the disclosure is achieved by following embodiments. In particular, a mirror display device is provided and comprises: a substrate; a cover disposed opposite to the substrate; a plurality of sub-pixels, the plurality of sub-pixels disposed between the substrate and the cover and arranged in an array, the plurality of sub-pixels comprising organic light emitting elements; a reflection layer disposed between the plurality of sub-pixels and the cover, and the reflection layer including a plurality of apertures, the plurality of apertures are corresponding to the plurality of sub-pixels in one-to-one correspondence.

Further, the mirror display device comprises a pixel defining layer disposed between the substrate and the reflection layer, and the pixel defining layer includes a plurality of pixel defining openings, the pixel defining openings are corresponding to the plurality of sub-pixels in one-to-one correspondence, and each of the plurality of sub-pixels is positioned in the plurality of pixel defining openings correspondingly.

Further, the mirror display device comprises a black matrix disposed between the pixel defining layer and the reflection layer, the black matrix includes a plurality of light-transmitting openings, and the plurality of light-transmitting openings are corresponding to the plurality of sub-pixels in one-to-one correspondence.

Further, the mirror display device comprises a plurality of color filters, the plurality of color filters are corresponding to the plurality of apertures in one-to-one correspondence, and each of the color filters is positioned in the plurality of the apertures correspondingly.

Further, the plurality of color filters comprise a plurality of red color filters, a plurality of blue color filters and a plurality of green color filters.

Further, the plurality of sub-pixels comprise a plurality of red organic light emitting elements, a plurality of blue organic light emitting elements and a plurality of green organic light emitting elements, the plurality of red organic light emitting elements are corresponding to the plurality of red color filters in one-to-one correspondence, the plurality of blue organic light emitting elements are corresponding to the plurality of blue color filters in one-to-one correspondence, and the plurality of green organic light emitting elements are corresponding to the plurality of green color filters in one-to-one correspondence.

Further, each of the plurality of sub-pixels comprises a white organic light emitting element, each of the red color filters is corresponding to at least one of the white organic light emitting elements, each of the blue color filters is corresponding to at least one of the white organic light emitting elements, and each of the green color filters is corresponding to at least one of the white organic light emitting elements.

Further, the mirror display device comprises a plurality of driving elements, the plurality of driving elements are disposed between the substrate and the plurality of sub-pixels, the plurality of driving elements are corresponding to the plurality of sub-pixels in one-to-one correspondence, each of the driving elements is configured to drive the plurality of sub-pixels correspondingly to emit light, and the plurality of driving elements comprise at least one transistor.

According to another aspect of the disclosure, the disclosure further provides a manufacturing method of the mirror display device comprises the following steps: forming a plurality of driving elements on a substrate; forming a pixel defining layer on the plurality of driving elements, the pixel defining layer including a plurality of pixel defining openings; forming a sub-pixel in each of the plurality of pixel defining openings, the sub-pixels comprising organic light emitting elements; forming a reflection layer on a cover, the reflection layer including a plurality of apertures, and the plurality of apertures are corresponding to the sub-pixels in one-to-one correspondence; forming a black matrix on the reflection layer, the black matrix including a plurality of light-transmitting openings, the light-transmitting openings are corresponding to the sub-pixels in one-to-one correspondence; and encapsulating the cover and the substrate.

Further, the manufacturing method of the mirror display device comprises: forming a color filter in each of the apertures, the color filters comprising a plurality of red color filters, a plurality of blue color filters and a plurality of green color filters.

Beneficial effect of this invention: removing parts of the reflection layer corresponding to each of the sub-pixels to increase the light transmissivity of each of the sub-pixels.

### BRIEF DESCRIPTION OF THE DRAWINGS

The above and other aspects, features, and advantages of the embodiments of the present invention will become more apparent from the following description taken in conjunction with the accompanying drawings. In the figures:

FIG. 1 is a side view of a mirror display device according to an embodiment of the disclosure;

FIG. 2 is a structural schematic view of a plurality of sub-pixels projected on a reflection layer according to an embodiment of the disclosure;

FIG. 3 is a side view of a mirror display device according to another embodiment of the disclosure;

FIG. 4 is a side view of a mirror display device according to yet other embodiment of the disclosure;

FIG. 5 is a flow chart of a manufacturing method of a mirror display device according to an embodiment of the disclosure;

### DETAILED DESCRIPTION OF PREFERRED EMBODIMENTS

The embodiments are described in details with reference to the accompanying drawings. However, the details of the structures and procedures of the embodiments are provided for exemplification, and the described details of the embodiments are not intended to limit the present invention. It is noted that not all embodiments of the invention are shown. Modifications and variations can be made without departing from the spirit of the invention to meet the requirements of the practical applications.

Further, the accompany drawings are simplified for clear illustrations of the embodiment; sizes and proportions in the drawings are not directly proportional to actual products, and shall not be construed as limitations to the present disclosure. Also, the identical and/or similar elements of the embodiments are designated with the same and/or similar reference numerals.

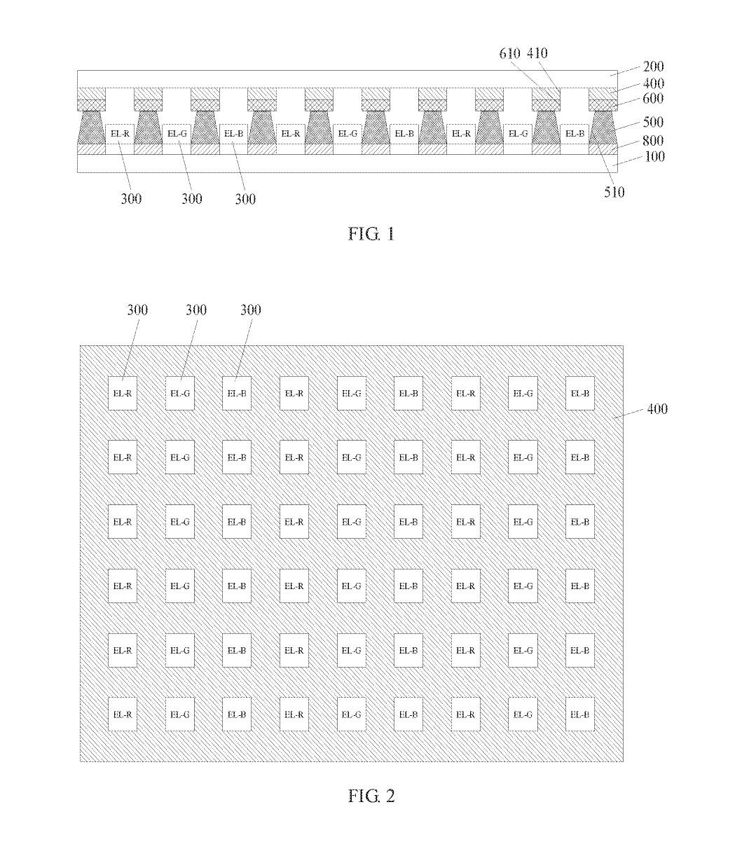

FIG. 1 is a side view of a mirror display device according to an embodiment of the disclosure.

Please refer to FIG. 1. A mirror display device according to an embodiment of the disclosure comprises: a substrate 100, a cover 200, a plurality of sub-pixels 300 and a reflection layer 400.

The cover 200 is disposed opposite to the substrate 100. The plurality of sub-pixels 300 are disposed on a surface of the substrate 100 facing the cover 200 and arranged in array; that is to say, the plurality of sub-pixels 300 disposed between the substrate 100 and the cover 200. In this embodiment, each of the sub-pixels 300 comprises an organic light emitting element, for example, OLED elements. The reflection layer 400 disposed on a surface of the cover 200 facing the substrate 100; that is to say, the reflection layer 400 is disposed between the plurality of sub-pixels 300 and the cover 200. The reflection layer 400 includes a plurality of apertures 410, and the apertures 410 are corresponding to the sub-pixels 300 in one-to-one correspondence.

Further, the size of the apertures 410 matches the size of the sub-pixels 300 so that the light emitting form the sub-pixels 300 could totally pass through the apertures 410, as shown in FIG. 2. FIG. 2 is a structural schematic view of a plurality of sub-pixels 300 projected on the reflection layer 400.

Therefore, the light transmissivity of each of the sub-pixels 300 could be increased by removing parts of the reflection layer 400 corresponding to the sub-pixels 300.

Further, the mirror display device according to an embodiment of the disclosure comprises: a pixel defining layer 500, the pixel defining layer 500 is disposed on the surface of the substrate 100 facing the cover 200; that is to say, the pixel defining layer 500 is disposed between the substrate 100 and the reflection layer 400. The pixel defining layer 500 includes a plurality of pixel defining openings 510, and the pixel defining openings 510 are corresponding to the sub-pixels 300 in one-to-one correspondence, each of the sub-pixels 300 is positioned in the pixel defining openings 510 correspondingly.

Further, the mirror display device according to an embodiment of the disclosure comprises: a black matrix 600, the black matrix is disposed on the reflection layer 400; that is to say, the black matrix 600 is disposed between the pixel defining layer 500 and the reflection layer 400. The black matrix 600 includes a plurality of light-transmitting openings 610, the light-transmitting openings 610 are corresponding to the sub-pixels 300 in one-to-one correspondence. In this embodiment, the black matrix 600 could prevent the reflection layer 400 from reflecting the light emitting from the sub-pixels 300, so that to avoid crosstalk between adjacent sub-pixels 300.

In order to drive each of the sub-pixels 300, the mirror display device according to an embodiment of the disclosure further comprises: a plurality of driving elements 800, the driving elements 800 are disposed between the substrate 100 and the sub-pixels 300, and the driving elements 800 are corresponding to the sub-pixels 300 in one-to-one correspondence, each of the driving elements 800 is configured to drive the sub-pixels 300 correspondingly to emit light, the driving elements 800 comprise at least one transistor.

FIG. 3 is a side view of a mirror display device according to another embodiment of the disclosure

Please refer to FIG. 3, the difference between FIG. 3 and FIG. 1 is: the mirror display device according to another embodiment of the disclosure further comprises a plurality of color filters 700, the color filters 700 are corresponding to the apertures 410 in one-to-one correspondence, and each of the color filters 700 is positioned in the corresponding one of the apertures 410.

In addition, in this embodiment, the color filters 700 could comprise a plurality of red color filters R, green color filters G, and blue color filters B, but the disclosure is not limited thereto.

In another embodiment of the disclosure, the color saturation of the mirror display device could be improved by disposing the color filters 700.

In another embodiment of the disclosure, the sub-pixels 300 comprise a plurality of red organic light emitting elements EL-R, a plurality of blue organic light emitting elements EL-B and a plurality of green organic light emitting elements EL-G, the red organic light emitting elements EL-R are corresponding to the red color filters R in one-to-one correspondence, the blue organic light emitting elements EL-B are corresponding to the blue color filters B in one-to-one correspondence, and the green organic light emitting elements EL-G are corresponding to the green color filters G in one-to-one correspondence.

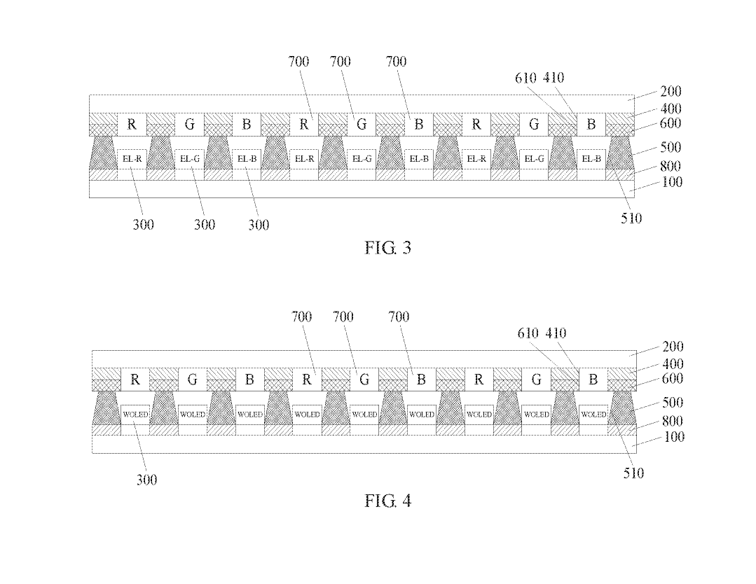

In yet other embodiment of the disclosure, as shown in FIG. 4, each of the sub-pixels 300 comprises a white organic light emitting element WOLED, each of the red color filters R is corresponding to a white organic light emitting element WOLED, each of the blue color filters B is corresponding to a white organic light emitting element WOLED, and each of the green color filters G is corresponding to at least one white organic light emitting element WOLED.

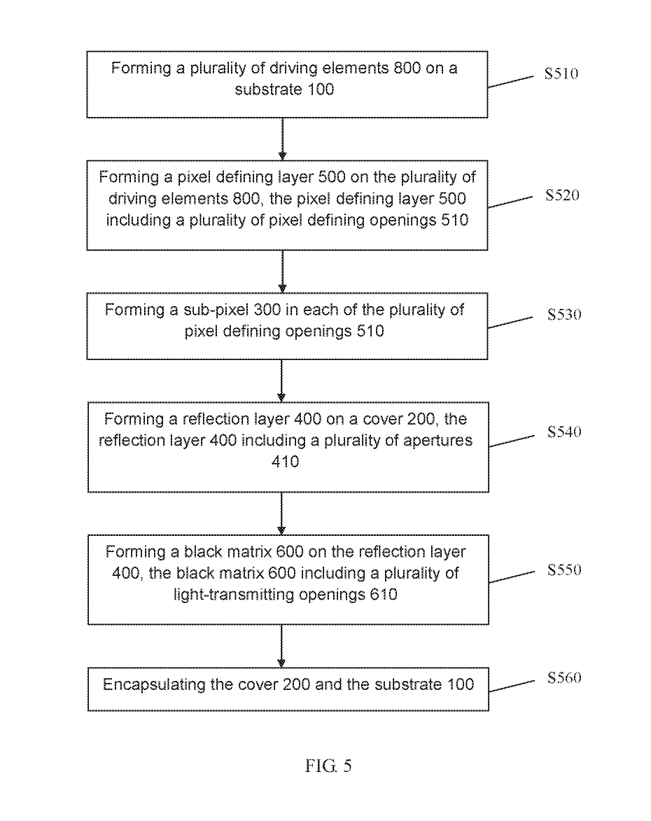

FIG. 5 is a flow chart of a manufacturing method of a mirror display device according to an embodiment of the disclosure, please refer to FIG. 1 to FIG. 5 together, the manufacturing method of the mirror display device according to an embodiment of the disclosure comprising the following steps:

Step S510: forming a plurality of driving elements 800 on a substrate 100. The driving elements 800 could be arranged in array, and each of the driving elements 800 comprises at least one transistor and at least one capacitor.

Step 520: forming a pixel defining layer 500 on the plurality of driving elements 800, the pixel defining layer 500 includes a plurality of pixel defining openings 510.

Step 530: forming a sub-pixel 300 in each of the pixel defining openings 510, the sub-pixels 300 comprise organic light emitting elements. The driving elements 800 are corresponding to the sub-pixels 300 in one-to-one correspondence, each of the driving elements 800 is configured to drive the corresponding sub-pixel 300 to emit light.

Step 540: forming a reflection layer 400 on a cover 200, the reflection layer 400 includes a plurality of apertures 410, and the apertures 410 are corresponding to the sub-pixels 300 in one-to-one correspondence.

Step 550: forming a black matrix 600 on the reflection layer 400, the black matrix 600 includes a plurality of light-transmitting openings 610, the light-transmitting openings 610 are corresponding to the sub-pixels 300 in one-to-one correspondence.

Step 560: encapsulation the cover 200 and the substrate 100.

In addition, after the step 550 and before the step 560, the manufacturing method of the mirror display device according to an embodiment of the disclosure further comprises: forming color filters 700 in corresponding apertures 410 and light-transmitting openings 610. In this embodiment, the color filters 700 could comprise a plurality of red color filters R, a plurality of green color filters G and a plurality of blue color filters B, the disclosure is not limited thereto.

In addition, in the manufacturing method of the mirror display device according to an embodiment of the disclosure, the sub-pixels 300 comprise a plurality of red organic light emitting elements EL-R, a plurality of blue organic light emitting elements EL-B and a plurality of green organic light emitting elements EL-G, the red organic light emitting elements EL-R are corresponding to the red color filters R in one-to-one correspondence, the blue organic light emitting elements EL-B are corresponding to the blue color filters B in one-to-one correspondence, and the green organic light emitting elements EL-G are corresponding to the green color filters G in one-to-one correspondence.

Alternatively, in the manufacturing method of the mirror display device according to an embodiment of the disclosure, as shown in FIG. 4, each of the sub-pixels 300 comprises a white organic light emitting element WOLED, each of the red color filters R is corresponding to a white organic light emitting element WOLED, each of the blue color filters B is corresponding to a white organic light emitting element WOLED, and each of the green color filters G is corresponding to at least one white organic light emitting element WOLED.

According to embodiments of the disclosure, the light transmissivity of each of the sub-pixels could be increased by removing parts of the reflection layer corresponding to the sub-pixels.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A mirror display device, comprising:
a substrate;
a cover disposed opposite to the substrate;
a plurality of sub-pixels, the plurality of sub-pixels disposed between the substrate and the cover and arranged in an array, wherein the plurality of sub-pixels comprise organic light emitting elements; and
a reflection layer disposed between the plurality of sub-pixels and the cover, and the reflection layer including a plurality of apertures, wherein the plurality of apertures are corresponding to the plurality of sub-pixels in one-to-one correspondence.

2. The mirror display device according to claim 1, wherein the mirror display device further comprises a pixel defining layer disposed between the substrate and the reflection layer, and the pixel defining layer including a plurality of pixel defining openings, the pixel defining openings are corresponding to the plurality of sub-pixels in one-to-one correspondence, and each of the plurality of sub-pixels is positioned in the plurality of pixel defining openings correspondingly.

3. The mirror display device according to claim 2, wherein the mirror display device further comprises a black matrix disposed between the pixel defining layer and the reflection layer, the black matrix includes a plurality of light-transmitting openings, and the plurality of light-transmitting openings are corresponding to the plurality of sub-pixels in one-to-one correspondence.

4. The mirror display device according to claim 1, wherein the mirror display device further comprises a plurality of color filters, the plurality of color filters are corresponding to the plurality of apertures in one-to-one correspondence, and each of the color filters is positioned in the plurality of the apertures correspondingly.

5. The mirror display device according to claim 2, wherein the mirror display device further comprises a plurality of color filters, the plurality of color filters are corresponding to the plurality of apertures in one-to-one correspondence, and each of the color filters is positioned in the plurality of the apertures correspondingly.

6. The mirror display device according to claim 3, wherein the mirror display device further comprises a plurality of color filters, the plurality of color filters are corresponding to the plurality of apertures in one-to-one correspondence, and each of the color filters is positioned in the plurality of the apertures correspondingly.

7. The mirror display device according to claim 4, wherein the plurality of color filters comprise a plurality of red color filters, a plurality of blue color filters and a plurality of green color filters.

8. The mirror display device according to claim 5, wherein the plurality of color filters comprise a plurality of red color filters, a plurality of blue color filters and a plurality of green color filters.

9. The mirror display device according to claim 6, wherein the plurality of color filters comprise a plurality of red color filters, a plurality of blue color filters and a plurality of green color filters.

10. The mirror display device according to claim 4, wherein the plurality of sub-pixels comprise a plurality of red organic light emitting elements, a plurality of blue organic light emitting elements and a plurality of green organic light emitting elements, the plurality of red organic light emitting elements are corresponding to the plurality of red color filters in one-to-one correspondence, the plurality of blue organic light emitting elements are corresponding to the plurality of blue color filters in one-to-one correspondence, and the plurality of green organic light emitting elements are corresponding to the plurality of green color filters in one-to-one correspondence.

11. The mirror display device according to claim 5, wherein the plurality of sub-pixels comprise a plurality of red organic light emitting elements, a plurality of blue organic light emitting elements and a plurality of green organic light emitting elements, the plurality of red organic light emitting elements are corresponding to the plurality of red color filters in one-to-one correspondence, the plurality of blue organic light emitting elements are corresponding to the plurality of blue color filters in one-to-one correspondence, and the plurality of green organic light emitting elements are corresponding to the plurality of green color filters in one-to-one correspondence.

12. The mirror display device according to claim 6, wherein the plurality of sub-pixels comprise a plurality of red organic light emitting elements, a plurality of blue organic light emitting elements and a plurality of green organic light emitting elements, the plurality of red organic light emitting elements are corresponding to the plurality of red color filters in one-to-one correspondence, the plurality of blue organic light emitting elements are corresponding to the plurality of blue color filters in one-to-one correspondence, and the plurality of green organic light emitting elements are corresponding to the plurality of green color filters in one-to-one correspondence.

13. The mirror display device according to claim 4, wherein each of the plurality of sub-pixels comprises a white organic light emitting element, each of the red color filters is corresponding to at least one of the white organic light emitting elements, each of the blue color filters is corresponding to at least one of the white organic light emitting elements, and each of the green color filters is corresponding to at least one of the white organic light emitting elements.

14. The mirror display device according to claim 5, wherein each of the plurality of sub-pixels comprises a white organic light emitting element, each of the red color filters is corresponding to at least one of the white organic light emitting elements, each of the blue color filters is corresponding to at least one of the white organic light emitting elements, and each of the green color filters is corresponding to at least one of the white organic light emitting elements.

15. The mirror display device according to claim 6, wherein each of the plurality of sub-pixels comprises a white organic light emitting element, each of the red color filters is corresponding to at least one of the white organic light emitting elements, each of the blue color filters is corresponding to at least one of the white organic light emitting elements, and each of the green color filters is corresponding to at least one of the white organic light emitting elements.

16. The mirror display device according to claim 1, wherein the mirror display device further comprises a plurality of driving elements, the plurality of driving elements are disposed between the substrate and the plurality of sub-pixels, the plurality of driving elements are corresponding to the plurality of sub-pixels in one-to-one correspondence, each of the driving elements is configured to drive the plurality of sub-pixels correspondingly to emit light, and the plurality of driving elements comprise at least one transistor.

17. A manufacturing method of a mirror display device, wherein comprises the following steps:
forming a plurality of driving elements on a substrate;
forming a pixel defining layer on the plurality of driving elements, the pixel defining layer including a plurality of pixel defining openings;
forming a sub-pixel in each of the plurality of pixel defining openings, the sub-pixels comprising organic light emitting elements;
forming a reflection layer on a cover, the reflection layer including a plurality of apertures, and the plurality of apertures are corresponding to the sub-pixels in one-to-one correspondence;
forming a black matrix on the reflection layer, the black matrix including a plurality of light-transmitting openings, the light-transmitting openings are corresponding to the sub-pixels in one-to-one correspondence; and
encapsulating the cover and the substrate.

18. The manufacturing method of the mirror display device according to claim 17, wherein further comprises:
forming a color filter in each of the plurality of apertures, the color filters comprising a plurality of red color filters, a plurality of blue color filters and a plurality of green color filters.
